(19) United States
(12) Patent Application Publication
(10) Pub. No.: US 2017/0053049 A1
(43) Pub. Date: Feb. 23, 2017

(54) PROCESS-SPECIFIC WAFER CARRIER CORRECTION TO IMPROVE THERMAL UNIFORMITY IN CHEMICAL VAPOR DEPOSITION SYSTEMS AND PROCESSES

(71) Applicant: Veeco Instruments Inc., Plainview, NY (US)

(72) Inventors: Lukas Urban, Princeton, NJ (US); Sandeep Krishnan, Jersey City, NJ (US)

(21) Appl. No.: 15/238,175

(22) Filed: Aug. 16, 2016

Related U.S. Application Data
(60) Provisional application No. 62/206,660, filed on Aug. 18, 2015.

(51) Int. Cl. G06F 17/50; C23C 16/18; C23C 16/52

(52) U.S. Cl. CPC G06F 17/5009; C23C 16/52; C23C 16/18; H01L 29/15

(57) ABSTRACT

Improvements to the heating uniformity of a wafer carrier for a chemical vapor deposition (CVD) system can be made based on a computational thermal model built according physical and operational characteristics of the CVD system. Operation of the thermal model is simulated, where a process recipe to be carried out on the CVD system is modeled, including heat transfers taking place in the virtual CVD system, to produce a set of thermal-spatial non-uniformities in at least one region of interest of a virtual wafer carrier. Structural corrections to be made to the pocket floor of each of the at least one wafer retention pocket are determined based on the set of thermal-spatial non-uniformities and on a predefined thermal-pocket floor relation that defines at least one design rule for correcting the pocket floor to achieve an increase in thermal uniformity throughout the at least one region of interest.

### RELATED APPLICATION INFORMATION

This application claims the benefit of U.S. Provisional Application 62/206,660, filed Aug. 18, 2015, which is hereby incorporated by reference.

### TECHNICAL FIELD

The present disclosure relates generally to systems and processes for fabrication of semiconductor devices. More particularly, the present disclosure relates to chemical vapor deposition (CVD) technologies directed to improving thermal uniformity in CVD processes by adjusting the structure of a wafer carrier based on thermal modeling of a CVD process.

### BACKGROUND

Certain processes for fabrication of semiconductors can require a complex process for growing epitaxial layers to create multilayer semiconductor structures for use in fabrication of high performance devices, such as light emitting diodes, laser diodes, optical detectors, power electronics, and field effect transistors. In this process, the epitaxial layers are grown through a general process called Chemical Vapor Deposition (CVD). One type of CVD process is called Metal Organic Chemical Vapor Deposition (MOCVD). In MOCVD, a reactor gas is introduced into a sealed reaction chamber within a controlled environment that enables the reactor gas to be deposited on a substrate (commonly referred to as a wafer) to grow thin epitaxial layers. Examples of current product lines for such manufacturing equipment include the TurboDisc®, MaxBright®, the EPIK® families of MOCVD systems, and the PROPEL® Power GaN MOCVD system, all manufactured by Veeco Instruments Inc. of Plainview, N.Y.

During epitaxial layer growth, a number of process parameters are controlled, such as temperature, pressure, and gas flow rate, to achieve desired quality in the epitaxial layer. Different layers are grown using different materials and process parameters. For example devices formed from compound semiconductor such as III-V semiconductors typically are formed by growing a series of distinct layers. In this process, the wafers are exposed to a combination of gases, typically including a metal organic compound as a source of group III metal, and also including a source of group V element which flow over the surface of the wafer while the wafer is maintained at an elevated temperature. Generally the metal organic compound and group V source are combined with a carrier gas which does not participate appreciably in the reaction, for example, nitrogen or hydrogen. One example of a III-V semiconductor is gallium nitride, which can be formed by reaction of organo-gallium compounds and ammonia on a substrate having a suitable crystal lattice spacing, for example a sapphire or silicon wafer. The wafer is usually maintained at a temperature on the order of 700-1200° C. during the deposition of the gallium nitride and/or related compounds. Another example of an III-V semiconductors indium phosphide (InP), which can be formed by reaction of indium and phosphine or aluminum gallium arsenide (AlGa₁₋ₓAsₓ), which can be formed by the reaction of aluminum, gallium and arsine, the reaction of the compounds forming a semiconductor layer on a suitable substrate.

In general, III V compounds can have the general formula In_{X}Ga_{Y}Al_{Z}N_{A}As_{B}P_{C}Sb_{D}, where X+Y+Z equals approximately one, A+B+C+D equals approximately one, and each of X, Y, Z, A, B, C, and D can be between zero and one. In some instances, bismuth may be used in place of some or all of the other Group III metals. Suitable substrate can be a metal, semiconductor, or an insulating substrate and can include sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

Another type of CVD process involves the growth of silicon carbide layers on substrates to form power electronic devices. Silicon carbide layers are grown using silanes and hydrocarbons as the reactive species with hydrogen as a carrier gas. The wafer is usually maintained at a temperature on the order of 800-2000° C. during deposition.

In a CVD process chamber, one or more semiconductor wafers are positioned within a tray, commonly referred to as a wafer carrier, so that the top surface of each wafer is exposed, thereby providing a uniform exposure of the top surface of the wafer to the atmosphere within the reaction chamber for the deposition of semiconductor materials. The wafer carrier is commonly rotated at a rotation speed on the order from about 100 to 1500 RPM or higher. The wafer carriers are typically machined out of a highly thermally conductive material such as graphite, and are often coated with a protective layer of material such as silicon carbide. Each wafer carrier has a set of circular indentations, or pockets, and its top surface in which the individual wafers are placed. Some examples of pertinent technology are described in U.S. Patent Publ. Nos. 2007/0186853 and 2012/0040097, and U.S. Pat. Nos. 6,492,625; 6,506,252; 6,902,623; 8,021,487; and 8,092,599, the disclosures of which are incorporated by reference herein. Other wafer carriers have a single pocket in which a single wafer is placed.

In some cases, the wafer carrier is supported on a spindle within the reaction chamber so that the top surface of the wafer carrier having the exposed surfaces of the wafers faces upwardly toward a gas distribution device. While the spindle is rotated, the gas is directed downwardly onto the top surface of the wafer carrier and flows across the top surface toward the periphery of the wafer carrier. The used gas can be evacuated from the reaction chamber through ports disposed below the wafer carrier. The wafer carrier can be maintained at the desired elevated temperature by heating elements, typically electric resistive heating elements disposed below the bottom surface of the wafer carrier. These heating elements are maintained at a temperature above the desired temperature of the wafer surfaces, where as the gas distribution device typically is maintained at a temperature well below the desired reaction temperature so as to prevent premature reaction of the gases. Therefore, heat is transferred from the heating elements to the bottom surface of the wafer carrier and flows upwardly through the wafer carrier to the one or more wafers.

In some cases, the wafer carrier can be supported and rotated by a rotational system that does not require a spindle. Such rotation system is described in U.S. Patent Application Publication No. 2015/0075431, the contents of which are incorporated by reference herein. In yet other cases, the wafer carrier can be placed facedown (inverted) in the reaction chamber and the gas injectors are mounted below the wafer carrier such that the gas mixture flows upwardly towards the one or more wafers. Examples of such inverted gas injection systems are described in U.S. Patent Publ. Nos. 2004/0060518 and 2004/0175939, and U.S. Pat. No. 8,133,322, the contents of which are incorporated by reference herein.

In a CVD process, the process parameters must be controlled with particular care to ensure that the chemical reaction proceeds under the required conditions. Even small variations in process conditions can adversely affect device quality and production yield. In particular, growing multiple quantum well (MQW) structures with the desired emission wavelength and optical properties requires precise control over the temperature, layer thickness, and composition on the wafer growth surface. Temperature variations on the surface of the wafer can cause variations in the composition and bandgap of a deposited layer. If, for example, the deposited layer is an active, light-emitting layer, the emission wavelength of any device formed from the wafer can vary to an unacceptable degree. Therefore, the growth temperature must be precisely controlled to achieve uniform material properties over the entire growth surface of the wafer in order to achieve a high process yield.

A great deal of effort has been devoted to system design features to minimize temperature variations during processing; however, the problem continues to present many challenges. In particular, the wafers are generally significantly less thermally conductive than the wafer carrier. For example, introducing a sapphire wafer in a pocket of the wafer carrier can create a heat-trapping or “blanketing” effect. This phenomenon can result in a generally radial thermal profile at the pocket floor which is hotter in the center where it is blanketed by the wafer, and lower temperature towards the outer radius of the pocket near the radial edge of the wafer.

Another effect that impacts thermal uniformity of the wafers in-process is the thermal gradient across the thickness of the wafer, which can cause a concave bow. In particular, when the bottom surface of the wafer is hotter than the top surface, the bottom surface may tend to expand more than the top surface, thereby creating a concave bow resulting in a gap forming between the bottom surface of the wafer and the pocket floor. As the gas within the gap typically has a lower thermal conductance than the wafer carrier, the concave bow can add significantly to the thermal non-uniformity that may already exist on the wafer due to thermal blanketing effects. This effect can be more pronounced in larger-diameter wafers, which are typically made from silicon. Also, with silicon wafers, the concave bow may be aggravated by film stresses from a crystal lattice mismatch between the silicon substrate and the deposited layers used to fabricate the devices on the substrate.

A further temperature gradient concern relates to multi-pocketed wafer carrier designs, wherein the pockets are arranged in concentric circles. During the CVD process, the reactor gas emitted from the gas distribution device passes over the wafer carrier in a generally spiral motion, originating proximal to the center of the wafer carrier and terminating at the radial edge of the wafer carrier. For high-speed rotating disc reactors, the spiral motion may have a relatively large tangential component. With concentric circle multi-pocketed wafer carrier designs, portions of the top surface of the wafer carrier between the concentric wafer pockets arrangements may form a circumferential band of top surface, uninterrupted by wafer pockets. Because the wafer carrier has a higher thermal conductivity, reactor gas with a large tangential component passing over these bands generally increases in temperature. As the reactor gas continues to spiral outwards, towards the radial edge of the wafer carrier, the reactor gas will encounter the next concentric arrangement of wafer pockets and begin to cool. Thus, the reactor gas may have a temperature gradient across the top surface of each wafer, wherein the temperature decreases with increasing distance from the center of the wafer carrier.

Thus, depending on the various geometries and processing parameters, such as the size, shape and construction of the process chamber, the temperature of the gasses, the temperature of the wafer carrier heating, the flow profile of the gasses, the speed of rotation of the wafer carrier, the time duration of various processing stages, etc., the characteristics of thermal non-uniformities are process-specific and system-specific. These thermal non-uniformities result in reduced yield and, consequently, higher unit cost.

U.S. Pat. No. 8,486,726, incorporated by reference herein, describes a novel improvement in the construction of wafer carriers to counteract some of the thermal non-uniformities. This reference discloses measuring one or more parameters of devices fabricated using the wafer carrier as a function of their corresponding positions on the substrate carrier. The parameters can be any type of parameter including, but not limited to, optical parameters, electrical parameters, or electro-optic parameters or, more generally, performance metrics, of an electrical or an optical device. In one specific embodiment, the parameter measured is the wavelength of optical emission generated by an optical device, such as a light emitting diode or a semiconductor laser. The measured parameters of deposited layers at some positions on the substrate are then related to a physical characteristic of the wafer carrier, such as the construction of structural features of the wafer carrier below or near the position of each of the wafers. The resulting data obtained from the measurement and analysis is then used to modify the wafer carrier or to fabricate a new wafer carrier with specifications that compensate for non-uniform process parameters associated with the substrate, such as temperature and/or gas phase non-uniformities, due to non-uniformities in the processing system. While this approach has been shown to be beneficial, obtaining measurements of fabricated device parameters can be burdensome, costly, or even logistically impracticable in some cases.

Solutions are needed that addresses one or more of these challenges in improving wafer heating uniformity in CVD reactors. In addition, solutions are needed that provide for improved wafer carriers with less heating non-uniformities while avoiding the difficulties associated with obtaining fabricated device performance-related characteristics.

### SUMMARY OF THE DISCLOSURE

Embodiments of the present disclosure meet the need for identifying and implementing physical changes to a wafer carrier for the purpose of reducing thermal spatial non-uniformities, and/or improving wafer heating uniformity without the need to obtain measurements of devices fabricated from wafers subjected to the CVD process. As such, embodiments of the present disclosure significantly improve the ability to achieve more uniform thermal properties over the entire growth surface of the wafer in order to achieve a higher process yield, without the added burden, cost and logistical difficulties in obtaining measurements of devices fabricated from wafers.

One embodiment of the present disclosure provides a system for customizing a wafer carrier for a chemical vapor deposition (CVD) system. Generally, the wafer carrier has a wafer carrier body formed symmetrically about a central axis, a generally planar top surface that is situated perpendicularly to the central axis, and at least one wafer retention pocket recessed in the wafer carrier body from the top surface, each of the at least one wafer retention pocket including a floor surface and a peripheral wall surface that surrounds the floor surface and defines a periphery of that wafer retention pocket. The system can be modeled on a computing platform including computing hardware having at least one processor, at least one data storage device, and input/output facilities, the at least one data storage device containing instructions. When executed, the instructions cause the computing platform to implement a thermal model generator engine, a thermal model simulator engine, and a pocket floor correction engine.

The thermal model generator engine reads process parameters defining (a) physical and operational characteristics of the CVD system including the wafer carrier, and (b) a process recipe to be carried out on the CVD system, and produces a thermal model, based on the physical and operational characteristics, that is a representation of a virtual CVD system.

The thermal model simulator engine computationally simulates operation of the thermal model carrying out at least a portion of the process recipe, including modeling of heat transfer taking place in the virtual CVD system. The thermal model simulator engine produces a set of thermal-spatial non-uniformities in at least one region of interest of at least one wafer retention pocket of a virtual wafer carrier modeled as part of the thermal model, at one or more stages of the process recipe.

The pocket floor correction engine computationally generates a representation of structural corrections to the pocket floor of each of the at least one wafer retention pocket of the wafer carrier modeled as part of the thermal model. The structural corrections are based on the set of thermal-spatial non-uniformities and on a predefined thermal-pocket floor relation that defines at least one design rule for correcting the pocket floor to achieve an increase in thermal uniformity throughout the at least one region of interest. Physical changes to the wafer carrier can be made based on the representation of structural corrections produced by the system for customizing the wafer carrier.

Another embodiment of the present disclosure provides a method is provided for customizing a wafer carrier for a chemical vapor deposition (CVD) system. In a computing system, a thermal model is produced, based on process parameters defining physical and operational characteristics of the CVD system including the wafer carrier. The computing system simulates operation of the thermal model carrying out at least a portion of a process recipe to be carried out on the CVD system, including modeling of heat transfer taking place in the virtual CVD system, the simulating producing a set of thermal-spatial non-uniformities in at least one region of interest of at least one wafer retention pocket of a virtual wafer carrier modeled as part of the thermal model, at one or more stages of the process recipe. Further, the method generates a representation of structural corrections to the pocket floor of each of the at least one wafer retention pocket of the wafer carrier modeled as part of the thermal model, the structural corrections being based on the set of thermal-spatial non-uniformities and on a predefined thermal-pocket floor relation that defines at least one design rule for correcting the pocket floor to achieve an increase in thermal uniformity throughout the at least one region of interest. Physical structural corrections corresponding to the representation of structural corrections, are made to an actual, physical wafer carrier, such that the wafer carrier is optimized to the thermal model and the modeled process recipe.

Another embodiment of the present disclosure provides a wafer carrier that includes a wafer carrier body formed symmetrically about a central axis, a generally planar top surface that is situated perpendicularly to the central axis, and at least one wafer retention pocket recessed in the wafer carrier body from the top surface, each of the at least one wafer retention pocket including a floor surface and a peripheral wall surface that surrounds the floor surface and defines a periphery of that wafer retention pocket. Also, the wafer carrier features heat transfer means for maintaining thermal uniformity for a wafer retained by the at least one wafer retention pocket. The heat transfer means are optimized to a thermal model based on parameters defining (a) physical and operational characteristics of the CVD system including the wafer carrier, and (b) a process recipe to be carried out on the CVD system, the thermal model representing of a virtual CVD system. Operation of the thermal model is computationally simulated for the virtual CVD system carrying out at least a portion of the process recipe, including modeling of heat transfer taking place in the virtual CVD system, the computational simulation producing a set of thermal-spatial non-uniformities in at least one region of interest of at least one wafer retention pocket of a virtual wafer carrier modeled as part of the thermal model, at one or more stages of the process recipe. The heat transfer means constitutes a physical implementation of computationally-generated structural corrections to the pocket floor of each of the at least one wafer retention pocket of the wafer carrier modeled as part of the thermal model, the structural corrections being based on the set of thermal-spatial non-uniformities and on a predefined thermal-pocket floor relation that defines at least one design rule for correcting the pocket floor to achieve an increase in thermal uniformity throughout the at least one region of interest.

The summary above is not intended to describe each depicted embodiment or every implementation of the present disclosure. The figures and the detailed description that follow more particularly exemplify these embodiments.

### BRIEF DESCRIPTION OF THE DRAWINGS

The disclosure can be more completely understood in consideration of the following detailed description of various embodiments of the disclosure, in connection with the accompanying drawings, in which:

FIG. 1A depicts a chemical vapor deposition (CVD) apparatus in accordance an embodiment of the disclosure.

FIG. 1B depicts a wafer carrier for use with the apparatus of FIG. 1A, and in accordance with an embodiment of the disclosure.

FIG. 2A depicts a partial, cross-sectional view of a wafer carrier having a wafer pocket containing a wafer, in accordance with an embodiment of the disclosure.

FIG. 2B illustrates a top-view of the wafer pocket of FIG. 2A, in accordance with an embodiment of the disclosure.

FIG. 3 is a block diagram depicting a modeling-thermal analyzing-pocket floor correction process, in accordance with an embodiment of the disclosure.

FIG. 4 is a visual representation of the sequence of data processing carried out by the modeling-thermal analyzing-pocket floor correction process of FIG. 3 is depicted in accordance with an embodiment of the disclosure.

FIG. 5 is a block diagram depicting a modeling-thermal analyzing-pocket floor correction process based at least partly on in-situ thermal measurements, in accordance with an embodiment of the disclosure.

FIG. 6 is a diagram depicting a computer system on which various aspects of a modeling-thermal analyzing-pocket floor correction process can be implemented at least in part, in accordance with an embodiment of the disclosure.

While embodiments of the disclosure are amenable to various modifications and alternative forms, specifics thereof are shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure as defined by the appended claims.

### DETAILED DESCRIPTION

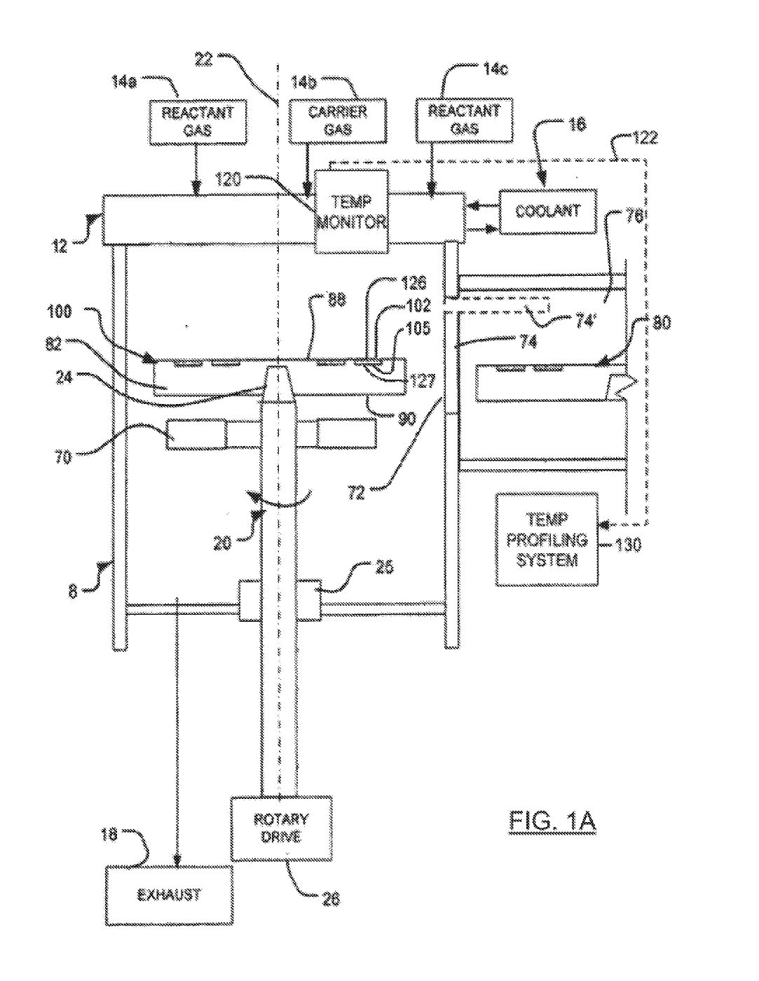

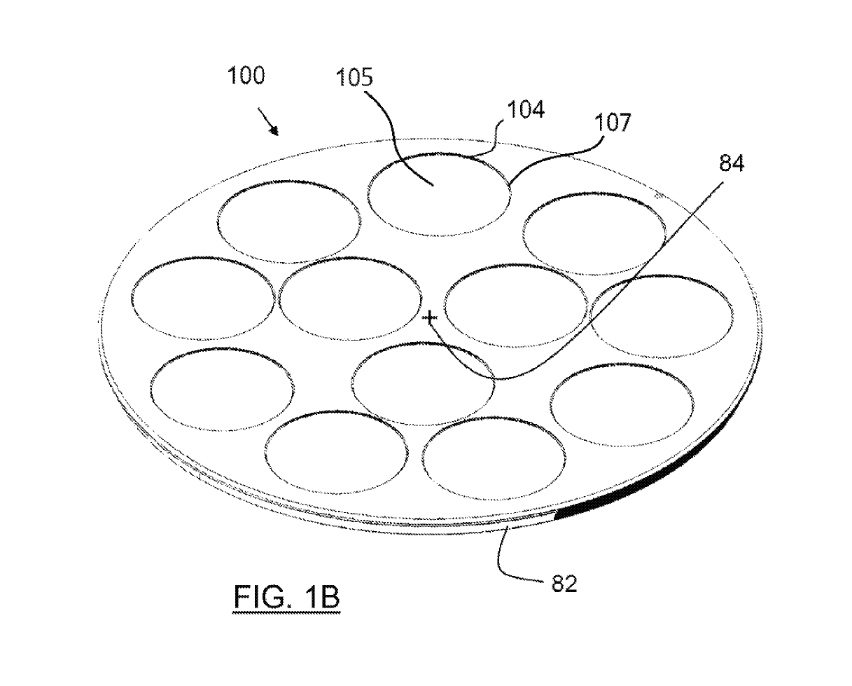

Referring to FIG. 1A, a chemical vapor deposition (CVD) apparatus is depicted in accordance with an embodiment of the disclosure. A reaction chamber 8 defines a process environment space. A gas distribution device 12 is arranged at one end of the chamber 8, referred to herein as the “top” end of the chamber 8. This end of the chamber 8 typically, but not necessarily, is disposed at proximate to the top of the CVD apparatus in the normal gravitational frame of reference. Thus, the downward direction as used herein refers to the direction away from the gas distribution device 12; whereas the upward direction refers to the direction within the chamber 8, toward the gas distribution device 12, regardless of whether these directions are aligned with the gravitational upward and downward directions. Similarly, the “top” and “bottom” surfaces of elements are described herein with reference to the frame of reference of chamber 8 and gas distribution device 12.

Gas distribution device 12 can be connected to gas supply units 14a, 14b, 14c for supplying process gases to be used in the wafer treatment process, such as a carrier gas and reactant gases such as a metalorganic compound and a source of a group V metal. In one embodiment, the process gas can be predominantly composed of a carrier gas, such as nitrogen, supplied by carrier gas supply unit 14b. Smaller amounts of reactive gas components, supplied by gas supply units 14a and 14c, can be carried by the carrier gas. The gas distribution device 12 is arranged to receive the various gases and direct a flow of process gasses generally in the downward direction. The gas distribution device 12 can also be connected to a coolant system 16 arranged to circulate coolant through the gas distribution device 12 so as to maintain the temperature of the gas distribution device 12 at a desired temperature during operation. A similar coolant arrangement (not shown) can be provided for cooling the walls of chamber 8. Chamber 8 can also be equipped with an exhaust system 18 arranged to remove spent gases from the interior of the chamber 8 through ports (not shown) at or near the bottom of the chamber 8 so as to enable continuous flow of gas in the downward direction from the gas distribution device 12.

A spindle 20 is arranged within the chamber so that the central axis 22 of the spindle extends in the upward and downward directions. In one embodiment, the spindle is mounted to the chamber by a conventional rotary pass-through device 25 incorporating bearings and seals (not shown) so that the spindle can rotate about axis 22, while maintaining a seal between the spindle and the wall of chamber 8. The spindle can have a fitting 24 at its top end (i.e., at the end of the spindle closest to the gas distribution device 12). As further discussed below, fitting 24 can be a wafer carrier retention mechanism configured to releasably engage a wafer carrier. For example, in one embodiment, the fitting 24 is a generally frustoconical element tapering toward the top end of the spindle and terminating at a flat top surface, wherein the frustoconical element is an element having the shape of a frustum of a cone. Spindle 20 can be operably coupled to a rotary drive mechanism 26 such as an electric motor drive, configured to rotate the spindle about axis 22.

A heating element 70 can be mounted within the chamber 8 to at least partially surround spindle 20 below fitting 24. Chamber 8 can also be provided with an entry opening 72 leading to an antechamber 76, and a door 74 for closing and opening the entry opening 72. Door 74 is depicted only schematically in FIG. 1, and is shown as movable between the closed position shown in solid lines, in which the door isolates the interior of chamber 8 from antechamber 76, and an open position shown in broken lines at 74′. Door 74 can be equipped with an appropriate control and actuation mechanism for moving it between the open position and closed position. In practice, the door 74 may include a shutter movable in the upward and downward directions as disclosed, for example, in U.S. Pat. No. 7,276,124, the disclosure of which is incorporated by reference herein. The apparatus depicted in FIG. 1A may further include a loading mechanism (not shown) capable of moving a wafer carrier from the antechamber 76 into the chamber 8 and engaging the wafer carrier with the spindle 20 in the operative condition, and also capable of moving a wafer carrier off of the spindle 20 and into antechamber 76.

The apparatus can also include one or more wafer carriers 100. As depicted in FIG. 1A, a first wafer carrier 100 can be disposed inside chamber 8 in an operative position, while a second wafer carrier 100 can be disposed within antechamber 76.

Each wafer carrier 100 can include a body 82, which can be substantially in the form of a circular disc having a central axis 84 (as depicted in FIG. 1B). Body 82 can be formed symmetrically about central axis 84. In the operative position, the central axis 84 of the wafer carrier body 82 can be coincident with the axis 22 of the spindle 20. Body 82 can be formed as a single piece or as a composite of plural pieces. For example, as disclosed in U.S. Patent Publ. No. 2009/0155028, the disclosure of which is incorporated by reference herein, the wafer carrier body can include a hub defining a small region of the body surrounding the central axis 84 and a larger portion defining the remainder of the disc-like body. Body 82 can be formed from materials which do not contaminate the process and which can withstand the temperatures encountered in the process. For example, body 82 can be formed largely or entirely from materials such as graphite, silicon carbide, or other refractory materials. Body 82 can generally have planar top surface 88 and a bottom surface 90 extending generally parallel to one another and generally perpendicular to the central axis 84 of the body 82. Body 82 can also have one or more wafer-holding features, such as a wafer pocket 104, defined by a peripheral wall surface 107 and a pocket floor 105, wherein the wafer pocket 104 is hold one or more wafers 102.

In operation, a wafer 102, such as a disc-like wafer formed from sapphire, silicon carbide, or other crystalline substrate, having a top surface 126 and a bottom surface 127 can be disposed within each pocket 104 of each wafer carrier 100. Typically, the wafer 102 has a thickness which is small in comparison to the dimensions of its major surfaces. For example, a circular wafer of about 2 inches (50 mm) in diameter may be about 430 μm thick or less. As depicted in FIG. 1A, the wafer can be disposed with its top surface 126 facing upwardly, so that the top surface 126 is exposed at the top of the wafer carrier 100, and its bottom surface 127 rests on the pocket floor 105 of wafer pocket 104. It should be noted that in various embodiments, wafer carrier 100 carries different quantities of wafers. For instance, in one embodiment, the wafer carrier 100 is configured to hold six wafers 102. In another embodiment, as depicted in FIG. 1B, wafer carrier 100 is configured to hold twelve wafers.

In a typical CVD process, a wafer carrier 100 with wafers 102 loaded therein is loaded from antechamber 76 into chamber 8 and placed in the operative position, as depicted in FIG. 1A. In this condition, the top surfaces of the wafers 102 face upwardly, towards the gas distribution device 12. Heating element 70 can be activated, and the rotary drive mechanism 26 can operate to turn spindle 20 and hence wafer carrier 100 around axis 22. In some embodiments, the spindle 20 is rotated at a rotational speed from about 50-1500 revolutions per minute. Process gas supply units 14a, 14b, and 14c are configured to supply gases through the gas distribution device 12. The gases pass downwardly toward the wafer carrier 100, over the top surface 88 of the wafer carrier 100 and the top surfaces 126 of the wafers 102, and downwardly around the periphery of the wafer carrier 100 to the outlet and to exhaust system 18. Thus, the top surface 88 of the wafer carrier 100 and the top surfaces 126 of the wafer 102 are exposed to a process gas including a mixture of the various gases supplied by the various gas supply units 14a-c.

One or more heaters 70 can be configured to transfer heat to the bottom surface 90 of the wafer carrier 100, principally by radiant heat transfer. The heat applied to the bottom surface 90 of the wafer carrier 100 flows upwardly through the body 82 of the wafer carrier 100 to the top surface 88 of the wafer carrier 100, as well as through the top surfaces 126 of the wafers 102. Heat is radiated from the top surface 88 of the wafer carrier 100 and from the top surfaces 126 of the wafers 102 to the cooler elements within the reaction chamber 8, such as the walls of the process chamber 8 and to the gas distribution device 12. Heat is also transferred from the top surface 88 of the wafer carrier 100 and the top surfaces 126 of the wafers 102 to the process gases passing over these surfaces.

As depicted in FIG. 1A, the CVD system can include features designed to determine uniformity of heating of the top surface 126 of each wafer 102. For example, in one embodiment, temperature profiling system 130 can be configured to receive temperature information 122 that can include temperature measurements from temperature monitor 120. For example, in one embodiment, temperature monitor 120 can be a noncontact instrument for measuring temperature, such as an optical pyrometer or infrared temperature sensor. In addition, temperature profiling system 130 can receive wafer carrier positional information, which in one embodiment can come from rotary drive mechanism 26. With this information, temperature profiling system 130 can construct a temperature profile of the wafers 102 on wafer carrier 100. The temperature profile can represent a thermal distribution on the surface 126 of each of the wafers 102. Examples of temperature monitor 120, temperature profiling system 130, and the operation thereof, is described in U.S. Patent Publ. No. 2013/0167769, the disclosure of which is incorporated by reference herein.

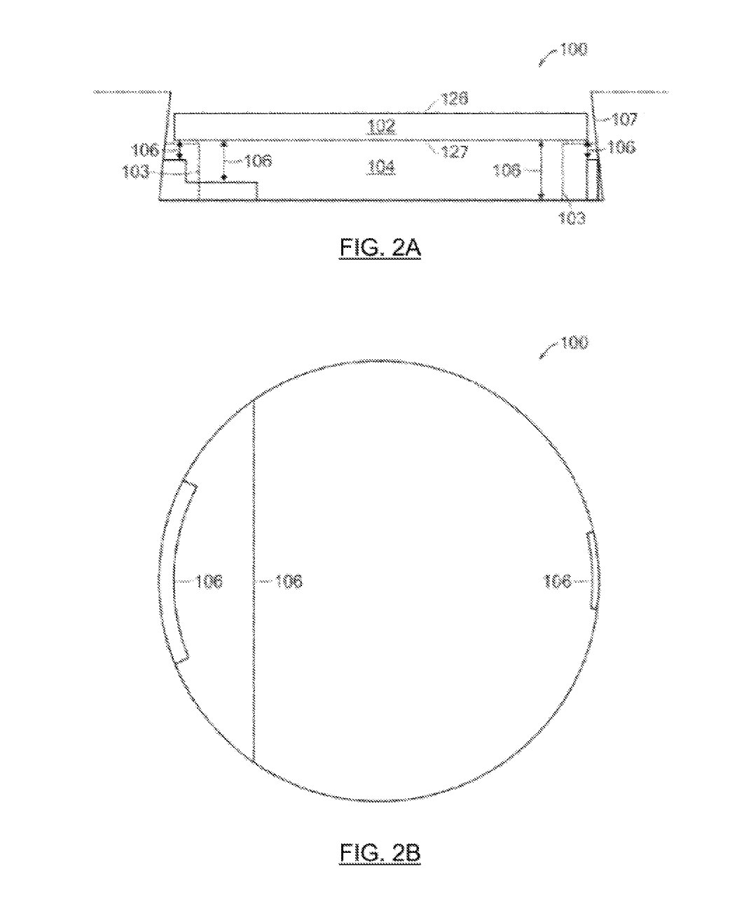

Referring to FIG. 2A, a partial, cross-sectional view of a wafer carrier 100 having a wafer pocket 104 containing a wafer 102 is depicted in accordance with an embodiment of the disclosure. FIG. 2B depicts a top view of the wafer pocket 104 of FIG. 2A. In one embodiment, the wafer carrier 100 can be formed of numerous types of materials, such as graphite, SiC, metal, or ceramic. In one embodiment, it is desirable to form the wafer carrier 100 of a material that can easily accept additional materials 103 in localized areas of different materials or the same material with a different orientation or with modified properties in localized areas. For example, as depicted in FIG. 2A, additional materials 103 added to the pocket floor 105 and/or peripheral wall surface 107 of the wafer pocket 104 can be configured to provide additional support for wafer 102 and/or compensate for thermal non-uniformities. In one embodiment, additional materials 103 can be added to or removed from the pocket floor 105 and/or the wall surface 107 by a contouring apparatus.

Additional materials 103 can be positioned at several locations along the peripheral wall surface 107 of the wafer 102. Additional materials 103 can be rectangular, stepped, triangular, or sloped in shape. Material 103 can be added, for example, by evaporation, sputtering, plating, CVD, or positioning an additional support therein. Portions of the wafer carrier 100 can be masked so that the additional material 103 is deposited in only certain areas of the wafer carrier 100. As depicted in FIG. 2B, the wafer pockets 104 and/or additional materials 103 can define various gaps or step heights 106 spanning from the pocket floor 105 to the bottom surface 127 of the wafer 102. In some embodiments, changes in the step height 106 can affect the thermal conductivity of the wafer carrier 100, so as to promote a more uniform temperature profile across the top surface 126 of the wafer 102.

In one embodiment, portions of the pocket floor 105 are contoured away to adjust the various step heights 106 spanning from the pocket floor 105 to the bottom surface 127 of the wafer 102. For example, in one embodiment, a wafer carrier 100 is initially produced with a pocket floor 105 having an elevation equal to the highest anticipated point within a finalized pocket floor 105, such that only the removal of material needs to be carried out to produce the final pocket floor 105. Material can be removed from the wafer carrier 100, for example, by machining localized areas in the pocket 104 of the wafer carrier 100. In such an embodiment, it is desirable to form the wafer carrier 100 of a material that can be easily machined in localized areas to conform to a predefined contour. The wafer carrier 100 can be machined with continuous contours or can be machined in localized areas by pecking with a specialized cutting tool. For example, a small diameter diamond cutting tool can be used. Cutting tools that operate at high speeds, such as cutting tools that use air turbine spindles can provide the relatively high accuracy needed for machining small pixels.

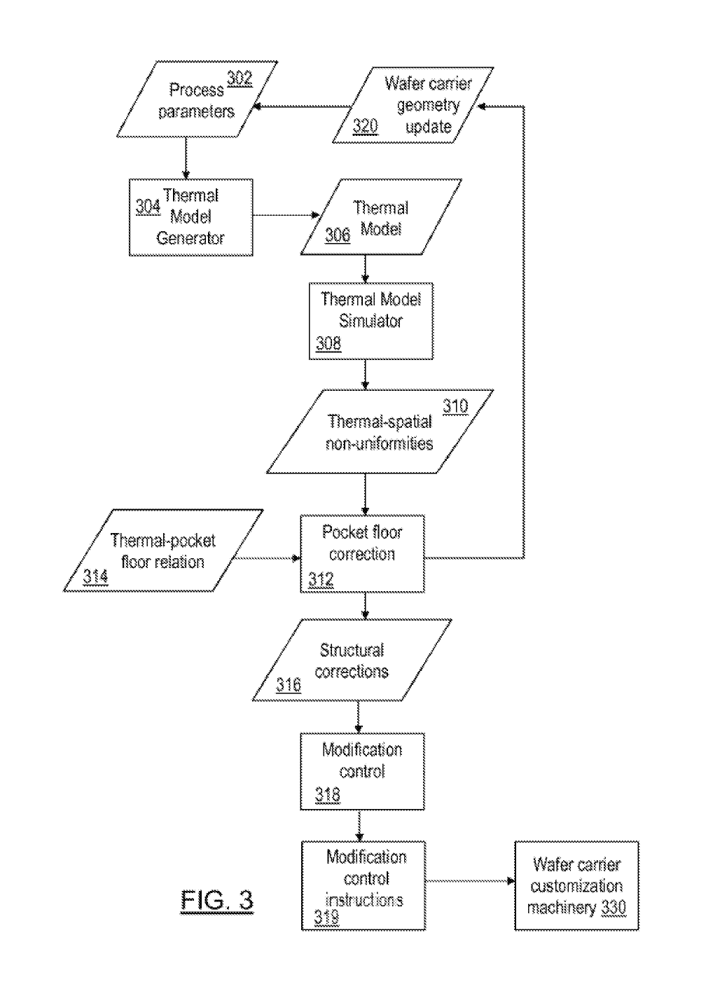

In one embodiment, a wafer carrier 100 can be manufactured or modified to improve wafer heating uniformity based on a thermal-spatial computational model of a CVD process that uses the wafer carrier 100. Referring to FIG. 3 a block diagram of a system configured to customize a wafer carrier 100 to improve wafer heating uniformity is depicted in accordance with an embodiment of the disclosure. The system can include a thermal model generator engine 304, thermal model simulator engine 308, pocket floor correction engine 312, and modification control engine 318.

In one embodiment, these engines can be implemented as part of a computer system. The computer system can be one physical machine, or can be distributed among multiple physical machines, such as by role or function, or by process thread in the case of a cloud computing distributed model. In various embodiments, aspects of the disclosure can be configured to run in virtual machines that in turn are executed on one or more physical machines. It will be understood by persons of skill in the art that embodiments of the disclosure may be realized by a variety of different suitable machine implementations.

More generally, each of the engines, can be programmed, or otherwise configured, to carry out a function or set of functions. In general, the term engine in the present context means a real-world device, component, or arrangement of components implemented using hardware, such as by an application specific integrated circuit (ASIC) or field-programmable gate array (FPGA), for example, or as a combination of hardware and software, such as by a microprocessor system and a set of program instructions that configure the engine to implement the particular functionality, which (while being executed) transform the microprocessor system into a special-purpose device. An engine can also be implemented as a combination of the two, with certain functions facilitated by hardware alone, and other functions facilitated by a combination of hardware and software. In certain implementations, at least a portion, and in some cases, all, of a engine can be executed on the processor(s) of one or more computers that execute an operating system, system programs, and application programs, while also implementing the engine using multitasking, multithreading, distributed (e.g., cluster, peer-peer, cloud, etc.) processing where appropriate, or other such techniques. Accordingly, each engine can be realized in a variety of suitable configurations, and should generally not be limited to any particular implementation exemplified herein, unless such limitations are expressly called out. In addition, an engine can itself be composed of more than one sub-engines, each of which can be regarded as a engine in its own right. Moreover, in the embodiments described herein, each of the various engines corresponds to a defined functionality; however, it should be understood that in other contemplated embodiments, each functionality may be distributed to more than one engine. Likewise, in other contemplated embodiments, multiple defined functionalities may be implemented by a single engine that performs those multiple functions, possibly alongside other functions, or distributed differently among a set of engines than specifically depicted in the examples herein.

Each process recipe is defined in terms of process parameters 302. Process parameters 302 can define the physical and operational characteristics of the CVD system (e.g., the construction and geometry of the reaction chamber 8 and of the wafer carrier 100, operational parameters that affect the materials, the flow of gasses, heating element 70 positioning, size, and geometry, heat flux and radiation within the reaction chamber 8 and in or about the wafer carrier 100, motion of the wafer carrier 100, gas pressure in the reaction chamber 8, and the like). Process parameters 302 can further define a process recipe to be carried out on the CVD system (e.g., the temperature set points, timing of events or operations of the process, etc.). Process parameters 302 can also define the characteristics of the wafers 102 to be used. In one embodiment, the process parameters 302 are embodied as one or more data structures stored in a tangible, non-transitory, computer readable data storage medium or media.

In one embodiment, thermal model generator engine 304 can read the process parameters 302, and create a thermal model 306, representing a virtual CVD system configured to accurately represent an actual CVD system over a period of time, for example the duration of the chemical reaction with any CVD system. For example, the thermal model 306 can compute the theoretical thermal radiation to and from one or more wafer 102 and/or the wafer carrier 100, based at least in part on the defined process parameters 302, thereby simulating the heat transfer taking place in the virtual CVD system while the process recipe is carried out. In one embodiment, the thermal model 306 takes into account the thermal blanketing effect of the wafer 102. In one embodiment, the thermal model 306 takes into account bowing of the wafer 102 based on the temperature and, optionally, based further on the structures and materials deposited or reacted on the wafer 102.

In one embodiment, the thermal model generator engine 304 can be used to model the heat transfer taking place in the virtual CVD system in a series of finite time increments spanning over a broader period of time, such that the resulting thermal model 306 can be used to determine a temperature gradient across a portion of the CVD system during any finite time increment, as well as changes to the temperature gradient over the broader time period. For example, a finite-element analysis (FEA) technique can be used to create the thermal model 306. Thermal model 306 can be embodied as one or more data structures stored in a tangible, non-transitory, computer-readable data storage medium or media, of a CVD system (including a process chamber, wafer carrier, heat source, and material flows, etc.).

In one embodiment, the thermal model simulator engine 308 runs the thermal model 306 to create a thermal spatial non-uniformity model 310. The thermal spatial non-uniformity model 310 represents the time-varying spatial temperature distribution at least one region of interest of at least one wafer 102 and/or wafer carrier 100, as a function of time. In one embodiment, the thermal spatial non-uniformities model 310 can produce a representation of the spatial distribution of the temperature of wafers 102, retained in the wafer carrier 100 as the simulated CVD process is carried out. Accordingly, in one embodiment, the dynamic thermal modeling 310 is derived not from measured emission wavelength of actual devices fabricated using the process, as described in U.S. Pat. No. 8,486,726, but from the computational modeling of one or more processes represented by the thermal model 306 without running those processes within an actual CVD system, thereby alleviating the need to fabricate real world components and significantly reducing the cost of testing.

The thermal spatial non-uniformities model 310 can represent the nominal temperature, as well as hotter and cooler parts, of the regions of interest. The output of the thermal model simulator 308 can include data representing the thermal-spatial non-uniformities 310 of the regions of interest one or more critical points within each process. For example, the thermal spatial non-uniformities model 310 can be particularized to when heat-sensitive parts of the fabricated devices are formed, such as during the formation of MQW structures. In one embodiment, the thermal spatial non-uniformities model 310 is created from more than one thermal model 306, such that the thermal spatial non-uniformities model 310 represents an average time-varying spatial temperature distribution at least one region of interest of at least one wafer 102 and/or wafer carrier 100 across the various thermal models 306.

In one embodiment, pocket floor correction engine 312 can generate a representation of the structural corrections 316 to be made to pocket floor 105 based on a function of the thermal spatial non-uniformities model 310 and a thermal pocket floor relation 314. The thermal-pocket floor relation 314 can define at least one design rule for modifying the pocket floor 105. For example, in one embodiment, the thermal-pocket floor relation 314 can define the thermal conductivity of various step heights 106 between the pocket floor 105 and the bottom surface 127 of the wafer 102 (e.g., the relationship between the proximity of the wafer 102 to the pocket floor 105 and temperature correction at a given nominal temperature). In one embodiment, the relationship between a given step height 106 a corresponding temperature differential can be defined as a distance per unit temperature (e.g., 6.8 microns per degree Celsius, wherein reduction of the pocket floor-wafer gap by 6.8 microns at a certain region of interest of the wafer pocket results in a temperature increase at the wafer of 1° C. over that region of interest).

In one embodiment, the thermal-pocket floor relation 314 includes a defined relationship that takes into account the locations of different regions of the wafer carrier pocket 104. For example, the distance-per-unit-temperature relation can be defined for a given point on the wafer 102 in terms of that point's radius from the center of the pocket 104. This refinement represents heat radiation not only from the pocket floor 105, but also from the peripheral wall 107 of the pocket 104 beneath the wafer 102, as well as heat conduction via contact points between wafer 102 and the peripheral wall 107 of the pocket 104 or the additional materials 103 on which the wafer 102 is supported over the pocket floor 105.

In one embodiment, the thermal-pocket floor relation 314 takes into account bowing of the wafer 102. The bowing correction can be a function of temperature, wafer thickness, wafer material, wafer diameter, device structures formed on the wafer 102, or any combination thereof. Notably, gallium arsenide and sapphire wafers 102 tend to bow such that the pocket floor 105 needs to be made more concave; whereas silicon wafers 102 tend to bow in the opposite direction, requiring the pocket floor 105 to be made more convex. The bowing correction can be based on empirical data as well as on a formula and interpolation to account for variations in processing conditions.

In one embodiment, thermal-pocket floor relation 314 includes rules for enhancing manufacturability of the pocket floor 105 construction. Examples of such rules include enforcement of minimum feature sizing (e.g., corresponding to machining tools, routing bit sizes, etc.), rules to maintain durability (e.g., avoiding narrow protrusions that might break during handling, cleaning, or processing using the wafer carrier), and rules to avoid corners or cavities where undesirable material build-up might occur and either affect the heating uniformity performance of the process, or present difficulty in cleaning the carrier.

The computed structural corrections 316 can represent modifications to the modeled profile of the pocket floor 105 that was used in the thermal model 306. In particular, the structural corrections 316 can serve to reduce thermal spatial non-uniformities. Structural corrections 316 can be applied to an actual, physical, wafer carrier 100 to improve the actual performance in an actual process that had been modeled. This can be accomplished by creating, or modifying the pocket floor 105, for instance, by adjusting step heights 106. As described above, material can be either added to or removed from the pocket 104.

In one embodiment, the structural corrections 316 are input to modification control engine 318, which generates modification control instructions 319 for actually making the modifications to the wafer carrier 100. For example, in one embodiment, modification control instructions 319 can be in the form of computer numerical control (CNC) machining instructions. In one embodiment, the modification control instructions 319 include mechanical drawings or other specifications that can be read and understood by a human operator. In one embodiment, the modification control instructions 319 include masking and processing instructions for a material deposition system to add material to a wafer carrier 100. Combinations of the various embodiments of the modification control instructions through 19 are also contemplated.

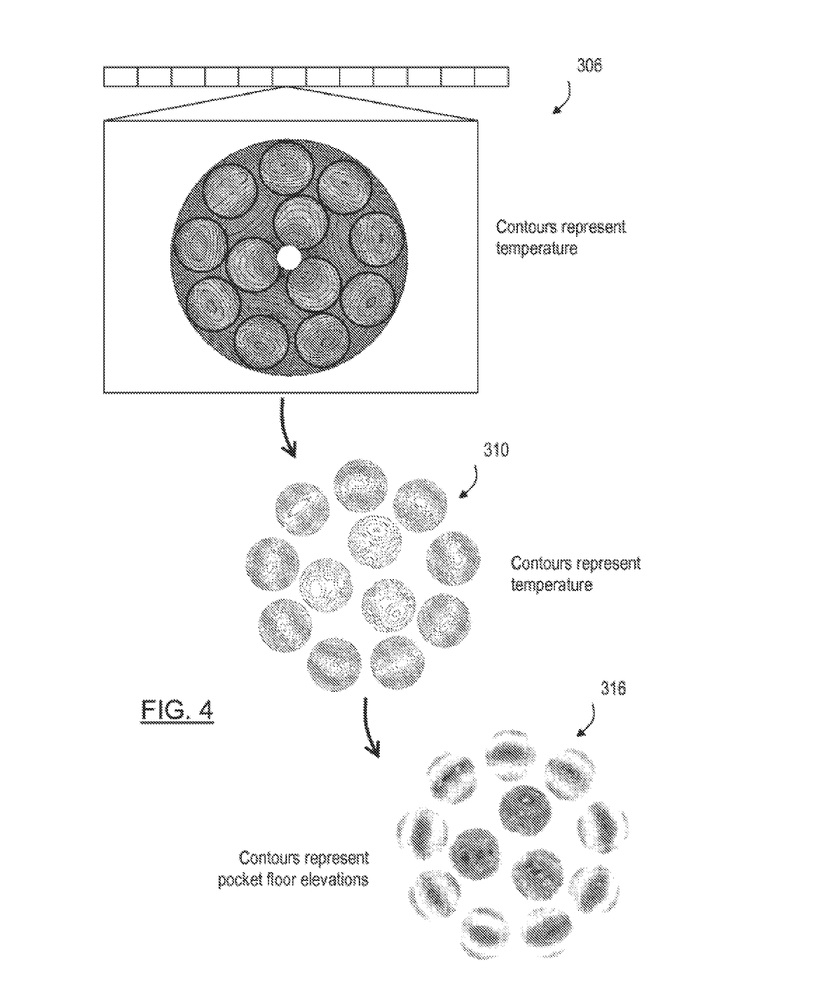

Referring to FIG. 4, a visual representation of the sequence of data processing carried out by the system of FIG. 3 is depicted in accordance with an embodiment of the disclosure. Thermal model 306 is a dynamic model, representing the thermal properties of the CVD system over a period of time. The thermal model 306 depicted in FIG. 4 represents the thermal properties of the wafer carrier 100 over a finite time increment within a broader period of time. After processing by thermal model simulator engine 308, a thermal spatial non-uniformities model 310 is produced, which represents a distribution of the temperature variations over the wafers 102. Here, the thermal information pertaining to the wafer carrier 100 is removed. Structural corrections 316 are computed as a function of the thermal spatial non-uniformities model 310 and the thermal-pocket floor relation 314. The contours depicted in structural corrections 316 in FIG. 4 represent the relative pocket floor elevations necessary to reduce the thermal non-uniformities of the thermal spatial non-uniformities model 310.

As further depicted in FIG. 3, in one embodiment, pocket floor correction engine 312 can additionally output a wafer carrier geometry update 320, which is an update to the model of the wafer carrier 100, which in turn, becomes incorporated into process parameters 302 from which a subsequent thermal model 306 is generated by thermal model generator engine 304. This operation constitutes an additional iteration of the modeling-thermal analyzing-pocket floor correction process, for further refinement of the modification control instructions 319. According to this approach, the corrected pocket floor profile is evaluated by the thermal model simulator engine 308.

In one embodiment, the thermal model simulator engine 308 compares the thermal-spatial non-uniformities results from the preceding and subsequent iterations, wherein if a predefined change threshold between a proceeding thermal spatial non-uniformities model 310 and a subsequent thermal spatial non-uniformities model 310 is exceeded, a further iteration is called for. If the change does not exceed the predefined change threshold, the pocket floor correction is deemed sufficiently optimized, and the structural corrections 316 for physical modification of the wafer carrier 100 can be outputted to the modification control engine 318.

Wafer carrier customization machinery block 330 represents one or more tools, machines, factories, and the like, that perform the physical wafer carrier modification to customize the wafer pocket 104 geometry according to the modification control instructions 319. The result of the wafer carrier 100 modification is a wafer carrier 100 having a pocket floor 105 geometry that is optimized to the computational model. Accordingly, the effectiveness of the physical wafer carrier 100 modification is subject to the accuracy of the computational model, thermal analysis 306, and structural corrections 316.

In various embodiments, process parameters 302, thermal model 306, thermal spatial non-uniformities model 310, thermal-pocket floor relation 314, structural corrections 316, modification control instructions 319, and wafer carrier geometry update 320 are each implemented as one or more data structures stored in a non-transitory computer-readable storage medium. Any suitable data structure form can be utilized including, but not limited to, files, strings, vectors, arrays, stacks, queues, linked lists, trees, databases, bitmaps, etc.

In other embodiments, multiple thermal models 306 are generated, which correspond to multiple different process recipes for which the wafer carrier 100 can be used. According to this approach, multiple dynamic models 310 are produced by thermal model simulator 308 and, prior to generating the structural corrections 316 by pocket floor correction engine 312, the dynamic models 310 corresponding to each process recipe modeled are computationally combined (e.g., by averaging, or otherwise aggregating) the various dynamic models 310 into a single map that represents the various process recipes. The structural corrections 316 that are then computed are no longer optimized to any one process recipe modeled; rather, they are optimized to an aggregated thermal spatial non-uniformities model 310.

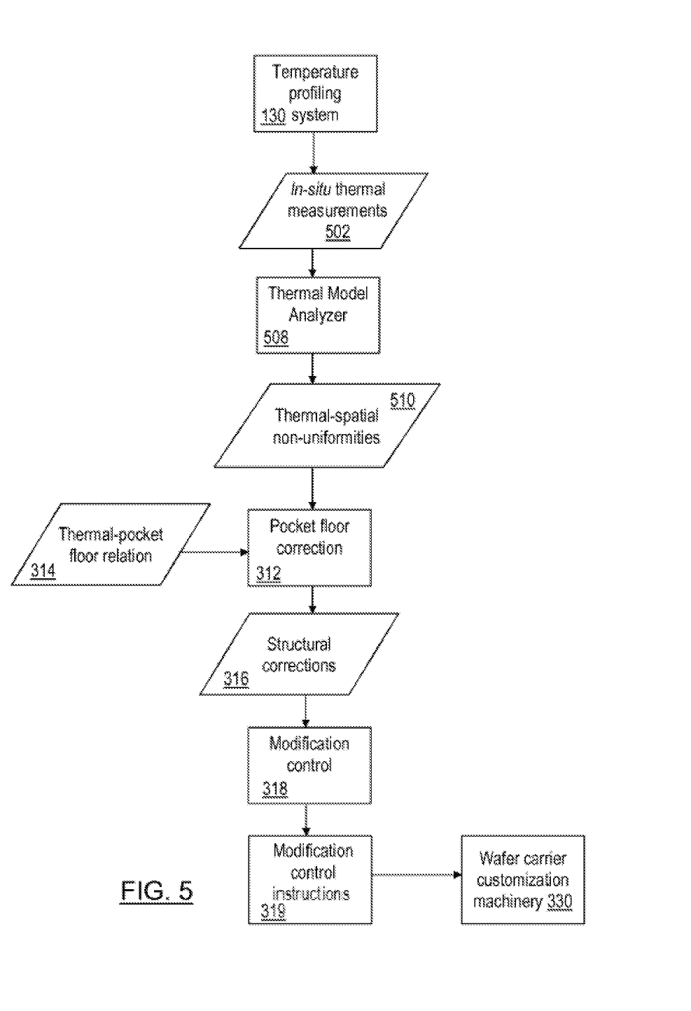

In some embodiments, the thermal model 306 is based on actual in-situ temperature measurements made during either actual processing in a CVD reaction chamber 8, or during a data gathering operation by the CVD system. Referring to FIG. 5, a system for customizing a wafer carrier 100 based on actual temperature measurement data is depicted in accordance with an embodiment of the disclosure. Temperature profiling system 130 constructs a temperature profile of the wafers 100, wafer pockets 104 or wafers 102, depending on the method of temperature data gathering. Accordingly, in-situ thermal measurements 502 are obtained by temperature profiling system 130 (described above) either as the temperature profile constructed, or based on further processing of the temperature profile. The in-situ thermal measurements 502 are provided to thermal model analyzer 508, which processes the in-situ thermal measurements 502 to produce thermal spatial non-uniformities model 510. Thermal spatial non-uniformities model 510 can be similar in principle to thermal spatial non-uniformities model 310 described above, except that this model is based on actual measured temperature data from a physical system, rather than on a purely computational model described above.

In one embodiment, the thermal model analyzer 508 performs specific processing to account for various phenomena or parasitic effects associated with the in-situ temperature measurement. For instance, in data collection runs that include wafers 102 placed in the wafer pockets 104, the temperature measured through the wafers 102 is no correct due to the wafers 102 absorbing or reflecting a portion of the radiated heat from the wafer carrier pockets 100. Accordingly, in one embodiment, a correction is applied to measured temperature for the inaccuracy introduced by the wafers' 102 presence. This correction can be based on an empirical understanding of the absorption/reflection characteristics, and can be defined as a function of wafer 102 dimensions and materials. In one embodiment, an interpolation correction is applied to offset measurement inaccuracies due to spots or other obstructions on a viewport of the temperature profiling system 130.

In one embodiment, the temperature measurement is conducted on an empty wafer carrier 100 (without wafers). Here, thermal model analyzer 508 simulates the effects of the wafer's presence, including heat transfer to the wafers 102, blanketing effect of the wafers 102, wafer 102 bowing, etc. In this example embodiment, the thermal-spatial non-uniformities 510 are obtained in part from actual in-situ thermal measurements, and in part on computational simulation.

The remaining elements depicted in FIG. 5 are marked with reference numerals that correspond with those present in FIG. 3, and are configured to operate as described above.

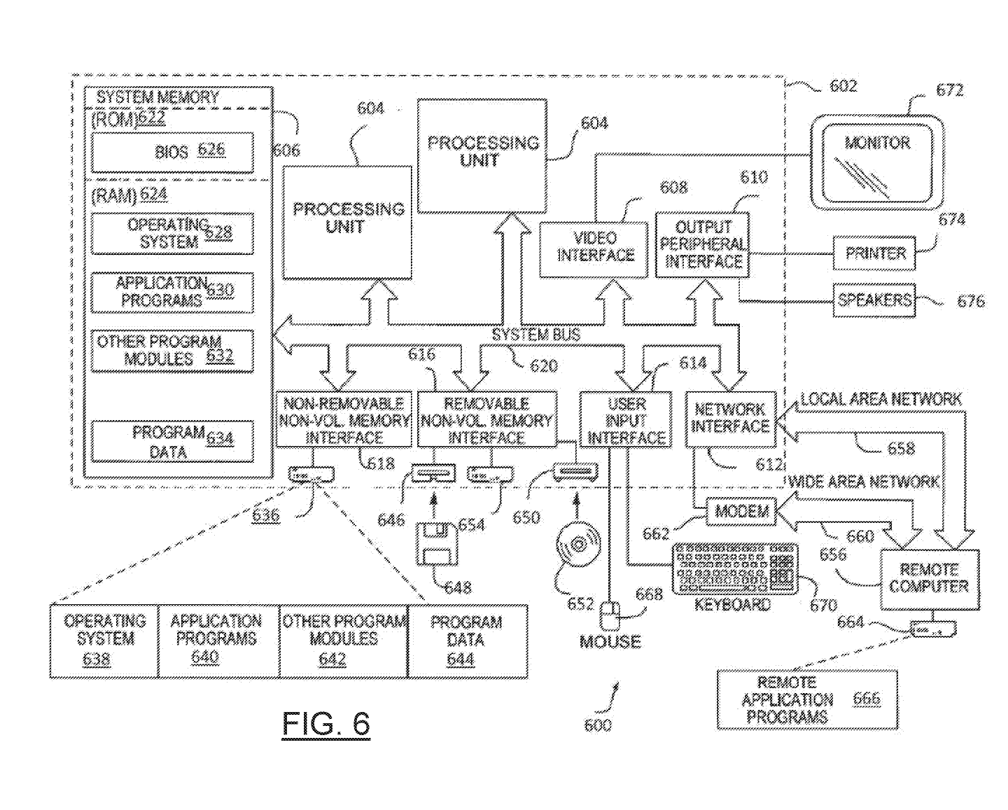

Referring to FIG. 6, a computer system 600 on which the modeling-thermal analyzing-pocket floor correction process can be implemented is depicted in accordance with an embodiment of the disclosure. The computer system 600 can include a computing device such as a personal computer 602. The personal computer 602 can include one or more processing units 604, a system memory 606, a video interface 608, an output peripheral interface 610, a network interface 612, a user input interface 614, removable 616 and non-removable 618 memory interfaces and a system bus or high-speed communications channel 620 coupling the various components. In one embodiment, the processing units 604 can have multiple logical cores that are able to process information stored on computer readable media such as the system memory 606 or memory attached to the removable 616 and non-removable 618 memory interfaces 618. The computer 602 system memory 606 can include non-volatile memory such as Read Only Memory (ROM) 622 or volatile memory such as Random Access Memory (RAM) 624. The ROM 622 can include a basic input/output system (BIOS) 626 to help communicate with the other portion of the computer 602. The RAM 624 can store portions of various software applications such as the operating system 628, application programs 630 and other program engines 632. Further, the RAM 624 can store other information such as program or application data 634. In one embodiment, the RAM 624 stores information that requires low-latencies and efficient access, such as programs and data being manipulated or operated on. In one embodiment, RAM 624 comprises Double Data Rate (DDR) memory, Error Correcting memory (ECC) or other memory technologies with varying latencies and configurations such as RAMBUS or DDR2 and DDR3. Accordingly, the system memory 606 can store the input data store, access credential data store, operating memory data store, instruction set data store, analysis result data store and the operating memory data store. Further, in one embodiment, the processing units 604 may be configured to execute instructions that limit access to the aforementioned data stores by requiring access credential before access to the information is granted.

The removable 616 and non-removable 618 memory interfaces may couple the computer 602 to disk drives 636 such as SSD or rotational disk drives. These disk drives 636 may provide further storage for various software applications such as the operating system 638, application programs 640 and other program engines 642. Further, the disk drives 636 can store other information such as program or application data 644. In one embodiment, the disk drives 636 store information that doesn't require the same low-latencies as in other storage mediums. Further, the operating system 638, application program 640 data, program engines 642 and program or application data 644 can be the same information as that stored in the RAM 624 in embodiments mentioned above or it may be different data potentially derivative of the RAM 624 stored data.

Further, the removable non-volatile memory interface 616 may couple the computer 602 to magnetic portable disk drives 646 that utilize magnetic media such as the floppy disk 648, Iomega® Zip or Jazz, or optical disk drives 650 that utilize optical media 652 for storage of computer readable media such as Blu-Ray®, DVD-R/RW, CD-R/RW and other similar formats. Still other embodiments utilize SSD or rotational disks housed in portable enclosures to increase the capacity of removable memory.

The computer 602 may utilize the network interface 612 to communicate with one or more remote computers 656 over a local area network (LAN) 658 or a wide area network (WAN) 660. The network interface 612 may utilize a Network Interface Card (NIC) or other interface such as a modem 662 to enable communication. The modem 662 can enable communication over telephone lines, coaxial, fiber optic, powerline, or wirelessly. The remote computer 656 can contain a similar hardware and software configuration or can have a memory 664 that contains remote application programs 666 that may provide additional computer readable instructions to the computer 602. In some embodiments, the remote computer memory 664 can be utilized to store information such as identified file information that may be later downloaded to local system memory 606. Further, the remote computer 656 can be an application server, an administrative server, client computers, or a network appliance.

A user may enter information into the computer 602 using input devices connected to the user input interface 614 such as a mouse 668 and keyboard 670. Additionally, the input device can be a trackpad, fingerprint scanner, joystick, barcode scanner, media scanner or the like. The video interface 608 may provide visual information to a display such as a monitor 672. The video interface 608 can be an embedded interface or it may be a discrete interface. Further, the computer may utilize a plurality of video interfaces 608, network interfaces 612 and removable 616 and non-removable 618 interfaces in order to increase the flexibility in operation of the computer 602. Further, various embodiments utilize several monitors 672 and several video interfaces 608 to vary the performance and capabilities of the computer 602. Other computer interfaces may be included in computer 602 such as the output peripheral interface 610. This interface may be coupled to a printer 674 or speakers 676 or other peripherals to provide additional functionality to the computer 602.

Various alternative configurations and implementations of the computer 602 are within the spirit of the disclosure. These variations may include, without limitation, additional interfaces coupled to the system bus 620 such as universal serial bus (USB), printer port, game port, PCI bus, PCI Express or integrations of the various components described above into chipset components such as the northbridge or southbridge. For example, in various embodiments, the processing unit 604 may include an embedded memory controller (not shown) to enable more efficient transfer of data from the system memory 606 than the system bus 620 may provide.

Persons of ordinary skill in the relevant arts will recognize that embodiments may comprise fewer features than depicted in any individual embodiment described above. The embodiments described herein are not meant to be an exhaustive presentation of the ways in which the various features may be combined. Accordingly, the embodiments are not mutually exclusive combinations of features; rather, embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Moreover, reference in the specification to “one embodiment,” “an embodiment,” or “some embodiments” means that a particular feature, structure, or characteristic, described in connection with the embodiment, is included in at least one embodiment of the teaching. The appearances of the phrase “in one embodiment” in various places in the specification are not necessarily all referring to the same embodiment.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of Section 112, sixth paragraph of 35 U.S.C. are not to be invoked unless the specific terms “means for” or “step for” are recited in a claim.

1. A system for customizing a wafer carrier for a chemical vapor deposition (CVD) system, wherein the wafer carrier has a wafer carrier body formed symmetrically about a central axis, a generally planar top surface that is situated perpendicularly to the central axis, and at least one wafer retention pocket recessed in the wafer carrier body from the top surface, each of the at least one wafer retention pocket including a floor surface and a peripheral wall surface that surrounds the floor surface and defines a periphery of that wafer retention pocket, the system comprising:
a computing platform including computing hardware having at least one processor, at least one data storage device, and input/output facilities, the at least one data storage device containing instructions that, when executed on the computing platform, cause the computing platform to implement:
a thermal model generator engine that reads process parameters defining (a) physical and operational characteristics of the CVD system including the wafer carrier, and (b) a process recipe to be carried out on the CVD system, and that produces a thermal model, based on the physical and operational characteristics, that is a representation of a virtual CVD system;
a thermal model simulator engine that computationally simulates operation of the thermal model carrying out at least a portion of the process recipe, including modeling of heat transfer taking place in the virtual CVD system, the thermal model simulator engine producing a set of thermal-spatial non-uniformities in at least one region of interest of at least one wafer retention pocket of a virtual wafer carrier modeled as part of the thermal model, at one or more stages of the process recipe;
a pocket floor correction engine that computationally generates a representation of structural corrections to the pocket floor of each of the at least one wafer retention pocket of the wafer carrier modeled as part of the thermal model, the structural corrections being based on the set of thermal-spatial non-uniformities and on a predefined thermal-pocket floor relation that defines at least one design rule for correcting the pocket floor to achieve an increase in thermal uniformity throughout the at least one region of interest.
a contouring apparatus configured to mechanically form, on the wafer carrier body, physical structural corrections corresponding to the representation of structural corrections, such that the wafer carrier is optimized to the thermal model.

2. The system of claim 1, wherein the thermal model is based in part on actual in situ temperature measurements made in a reaction chamber of a physical CVD system.

3. The system of claim 1, further comprising:
a modification control engine, implemented via the computing platform, that reads the representation of the structural corrections and computationally generates instructions for making physical modifications to a physical wafer carrier in accordance with the structural corrections.

4. The system of claim 1, wherein the pocket floor correction engine additionally outputs a wafer carrier geometry update that defines changes to the virtual wafer carrier, and wherein the thermal model generator engine is configured to produce a new thermal model based on the changes to the virtual wafer carrier being applied, and compare results of simulation of the new thermal model with those of a previous thermal model.

5. The system of claim 1, wherein the representation of the virtual CVD system includes a representation of a virtual process chamber, a virtual wafer carrier, a virtual heat source, and virtual material flows, corresponding to the process recipe.

6. The system of claim 1, wherein the thermal model simulator engine processes a dynamic model that represents time-varying spatial temperature distribution of the at least one region of interest, as a function of time, as the process recipe is carried out by the virtual CVD apparatus.

7. The system of claim 1, wherein the one or more stages of the process recipe at which the thermal model simulator engine produces the set of thermal-spatial non-uniformities represent critical points of a fabrication process during which quantum well structures are formed.

8. The system of claim 1, wherein the thermal model simulator engine simulates a thermal blanketing effect of the wafer on the temperature of the region of interest.

9. The system of claim 1, wherein the thermal model simulator engine simulates bowing of the wafer based on the temperature.

10. The system of claim 1, wherein the thermal model generator engine produces multiple thermal models, each of which corresponds to a different process recipe, and wherein the set of thermal-spatial non-uniformities is based on a combination of the multiple thermal models.

11. The system of claim 1, wherein the thermal-pocket floor relation takes into account bowing of the wafer as a function of process conditions.

12. The system of claim 1, wherein the thermal-pocket floor relation includes rules that take into account ease of manufacturability of the pocket floor correction.

13. The system of claim 1, wherein the at least one region of interest of the at least one wafer retention pocket of the virtual wafer carrier includes a virtual wafer modeled as part of the virtual wafer carrier.

14. The system of claim 1, wherein the at least one region of interest of the at least one wafer retention pocket of the virtual wafer carrier consists essentially of a virtual wafer in each of the at least one wafer retention pockets, the virtual wafer modeled as part of the virtual wafer carrier.

15. A method for customizing a wafer carrier for a chemical vapor deposition (CVD) system, wherein the wafer carrier has a wafer carrier body formed symmetrically about a central axis, a generally planar top surface that is situated perpendicularly to the central axis, and at least one wafer retention pocket recessed in the wafer carrier body from the top surface, each of the at least one wafer retention pocket including a floor surface and a peripheral wall surface that surrounds the floor surface and defines a periphery of that wafer retention pocket, the method comprising:
producing, by the computing system, a thermal model, based on process parameters defining physical and operational characteristics of the CVD system including the wafer carrier;
simulating, by the computing system, operation of the thermal model carrying out at least a portion of a process recipe to be carried out on the CVD system, including modeling of heat transfer taking place in the virtual CVD system, the simulating producing a set of thermal-spatial non-uniformities in at least one region of interest of at least one wafer retention pocket of a virtual wafer carrier modeled as part of the thermal model, at one or more stages of the process recipe;
generating, by the computing system, a representation of structural corrections to the pocket floor of each of the at least one wafer retention pocket of the wafer carrier modeled as part of the thermal model, the structural corrections being based on the set of thermal-spatial non-uniformities and on a predefined thermal-pocket floor relation that defines at least one design rule for correcting the pocket floor to achieve an increase in thermal uniformity throughout the at least one region of interest; and
mechanically forming, on the wafer carrier body, physical structural corrections corresponding to the representation of structural corrections, such that the wafer carrier is optimized to the thermal model.

16. The method of claim 15, further comprising:
taking actual in situ temperature measurements during operation of a physical CVD system; and
wherein the thermal model is based in part on the actual in situ temperature measurements.

17. The method of claim 15, further comprising:
generating, based on the representation of structural corrections, a wafer carrier geometry update that defines changes to the virtual wafer carrier;
producing a new thermal model based on the changes to the virtual wafer carrier being applied; and
comparing results of simulation of the new thermal model with those of a previous thermal model to produce a determination of a need for further thermal modeling and simulation.

18. The method of claim 15, wherein the representation of the virtual CVD system includes a representation of a virtual process chamber, a virtual wafer carrier, a virtual heat source, and virtual material flows, corresponding to the process recipe.

19. The method of claim 15, wherein in the simulating, a dynamic model is simulated that represents time-varying spatial temperature distribution of the at least one region of interest, as a function of time, as the process recipe is carried out by the virtual CVD apparatus.

20. The method of claim 15, wherein the one or more stages of the process recipe at which the set of thermal-spatial non-uniformities are produced represent critical points of a fabrication process during which quantum well structures are formed.

21. The method of claim 15, wherein in the simulating, a thermal blanketing effect of the wafer on the temperature of the region of interest is simulated.

22. The method of claim 15, wherein in the simulating, bowing of the wafer based on temperature is simulated.

23. The method of claim 15, wherein multiple thermal models are produced, each of which corresponds to a different process recipe, and wherein the set of thermal-spatial non-uniformities is based on a combination of the multiple thermal models.

24. The method of claim 15, wherein the thermal-pocket floor relation takes into account bowing of the wafer as a function of process conditions.

25. The method of claim 15, wherein the thermal-pocket floor relation includes rules that take into account ease of manufacturability of the pocket floor correction.

26. The method of claim 15, wherein the at least one region of interest of the at least one wafer retention pocket of the virtual wafer carrier includes a virtual wafer modeled as part of the virtual wafer carrier.

27. The method of claim 15, wherein the at least one region of interest of the at least one wafer retention pocket of the virtual wafer carrier consists essentially of a virtual wafer in each of the at least one wafer retention pockets, the virtual wafer modeled as part of the virtual wafer carrier.

28. A wafer carrier for a chemical vapor deposition (CVD) system, comprising:
a wafer carrier body formed symmetrically about a central axis;
a generally planar top surface that is situated perpendicularly to the central axis;
and at least one wafer retention pocket recessed in the wafer carrier body from the top surface, each of the at least one wafer retention pocket including a floor surface and a peripheral wall surface that surrounds the floor surface and defines a periphery of that wafer retention pocket; and
heat transfer means for maintaining thermal uniformity for a wafer retained by the at least one wafer retention pocket, the heat transfer means being optimized to a thermal model based on parameters defining (a) physical and operational characteristics of the CVD system including the wafer carrier, and (b) a process recipe to be carried out on the CVD system, the thermal model representing of a virtual CVD system;
wherein operation of the thermal model is computationally simulated for the virtual CVD system carrying out at least a portion of the process recipe, including modeling of heat transfer taking place in the virtual CVD system, the computational simulation producing a set of thermal-spatial non-uniformities in at least one region of interest of at least one wafer retention pocket of a virtual wafer carrier modeled as part of the thermal model, at one or more stages of the process recipe; and
wherein the heat transfer means constitutes a physical implementation of computationally-generated structural corrections to the pocket floor of each of the at least one wafer retention pocket of the wafer carrier modeled as part of the thermal model, the structural corrections being based on the set of thermal-spatial non-uniformities and on a predefined thermal-pocket floor relation that defines at least one design rule for correcting the pocket floor to achieve an increase in thermal uniformity throughout the at least one region of interest.
